(19) United States
(12) Patent Application Publication
(10) Pub. No.: US 2026/0344466 A1
(43) Pub. Date: Oct. 29, 2026

(54) ELECTRONIC PACKAGE STRUCTURE AND METHOD FOR MANUFACTURING THE SAME

(71) Applicant: ASE ELECTRONICS INC., KAOHSIUNG CITY (TW)

(72) Inventors: Ying-Ren CHANG, Kaohsiung City (TW); Yan-Feng LEE, Kaohsiung City (TW); Yita LU, Kaohsiung City (TW); Yung-Chi CHIANG, Kaohsiung City (TW); Che-Yuan CHANG, Kaohsiung City (TW); Cheng-Yuan CHEN, Kaohsiung City (TW); Sheng-Chun HO, Kaohsiung City (TW)

(73) Assignee: ASE ELECTRONICS INC., KAOHSIUNG CITY (TW)

(21) Appl. No.: 19/190,508

(22) Filed: Apr. 25, 2025

(51) Int. Cl. H10W 70/63; H10W 70/69; H10W 72/50; H10W 90/00

(52) U.S. Cl. CPC H10W 70/635; H10W 70/69; H10W 72/5434; H10W 90/756

(57) ABSTRACT

An electronic package structure includes a substrate structure and a conductive wire. The substrate structure includes a circuit layer, a dielectric layer and a booster layer. The circuit layer includes a pad portion. The dielectric layer encapsulates the circuit layer, and defines an opening exposing a top surface of the pad portion. An elevation of the top surface of the pad portion is lower than an elevation of a top surface of the dielectric layer. The booster layer is disposed on the pad portion of the circuit layer and extends beyond the top surface of the dielectric layer. The conductive wire is disposed on the booster layer.

### BACKGROUND

### 1. Field of the Disclosure

The present disclosure relates to an electronic package structure and a manufacturing method, and to an electronic package structure including a booster layer and a method for manufacturing the same.

### 2. Description of the Related Art

Along with the rapid development of electronic industries and the progress of semiconductor processing technologies, semiconductor chips are integrated with more electronic components to achieve better electrical performance. Accordingly, the semiconductor chips are provided with more input/output (I/O) connections. To manufacture semiconductor packages including semiconductor chips including an increased number of I/O connections, sizes of the semiconductor chips and the semiconductor packages may correspondingly increase. To minimize sizes of semiconductor packages including semiconductor chips including an increased number of I/O connections, a bonding pad density of semiconductor substrates used for carrying the semiconductor chips should correspondingly increase. Thus, a bonding between the semiconductor chip and the bonding pad is a critical issue.

### SUMMARY

In some embodiments, an electronic package structure includes a substrate structure and a conductive wire. The substrate structure includes a circuit layer, a dielectric layer and a booster layer. The circuit layer includes a pad portion. The dielectric layer encapsulates the circuit layer, and defines an opening exposing a top surface of the pad portion. An elevation of the top surface of the pad portion is lower than an elevation of a top surface of the dielectric layer. The booster layer is disposed on the pad portion of the circuit layer and extends beyond the top surface of the dielectric layer. The conductive wire is disposed on the booster layer.

In some embodiments, an electronic package structure includes a circuit layer, a dielectric layer and a booster layer. The circuit layer includes a pad portion. The dielectric layer encapsulates the circuit layer, and defines an opening exposing a top surface of the pad portion. The top surface of the pad portion is lower than a top surface of the dielectric layer. The booster layer is disposed on the pad portion of the circuit layer, and is configured to reduce a delamination between a conductive wire and the dielectric layer caused by a misalignment between the conductive wire and the pad portion of the circuit layer during a wire bonding process.

In some embodiments, an electronic package structure includes a substrate structure and a conductive wire. The substrate structure includes a circuit layer and a dielectric layer. The circuit layer includes a pad portion. The dielectric layer encapsulates the circuit layer, and defines an opening exposing a top surface of the pad portion. The top surface of the pad portion is lower than a top surface of the dielectric layer. The conductive wire electrically connects and is distant from the pad portion. An elevation of a bottom surface of the conductive wire is higher than an elevation of the top surface of the pad portion.

### BRIEF DESCRIPTION OF THE DRAWINGS

Aspects of some embodiments of the present disclosure are readily understood from the following detailed description when read with the accompanying figures. It is noted that various structures may not be drawn to scale, and dimensions of the various structures may be arbitrarily increased or reduced for clarity of discussion.

FIG. 1 illustrates a cross-sectional view of a portion of an electronic package structure according to some embodiments of the present disclosure.

FIG. 2 illustrates an enlarged view of an area “A” of FIG. 1.

FIG. 3 illustrates an enlarged view of an area “B” of FIG. 1.

FIG. 4 illustrates a cross-sectional view of a first portion of the first circuit layer and a booster layer according to some embodiments of the present disclosure.

FIG. 5 illustrates a cross-sectional view of a portion of an electronic package structure according to some embodiments of the present disclosure.

FIG. 6 illustrates an enlarged view of an area “C” of FIG. 5.

FIG. 7 illustrates an enlarged view of an area “D” of FIG. 5.

FIG. 7A illustrates an enlarged cross-sectional view of a portion of an electronic package structure according to some embodiments of the present disclosure.

FIG. 7B illustrates an enlarged cross-sectional view of a portion of an electronic package structure according to some embodiments of the present disclosure.

FIG. 8 illustrates a cross-sectional view of a portion of an electronic package structure according to some embodiments of the present disclosure.

FIG. 9 illustrates an enlarged view of an area “E” of FIG. 8.

FIG. 10 illustrates a cross-sectional view of a portion of an electronic package structure according to some embodiments of the present disclosure.

FIG. 11 illustrates one or more stages of an example of a method for manufacturing an electronic package structure according to some embodiments of the present disclosure.

FIG. 12 illustrates one or more stages of an example of a method for manufacturing an electronic package structure according to some embodiments of the present disclosure.

FIG. 13 illustrates one or more stages of an example of a method for manufacturing an electronic package structure according to some embodiments of the present disclosure.

FIG. 14 illustrates one or more stages of an example of a method for manufacturing an electronic package structure according to some embodiments of the present disclosure.

FIG. 15 illustrates one or more stages of an example of a method for manufacturing an electronic package structure according to some embodiments of the present disclosure.

FIG. 16 illustrates one or more stages of an example of a method for manufacturing an electronic package structure according to some embodiments of the present disclosure.

FIG. 17 illustrates one or more stages of an example of a method for manufacturing an electronic package structure according to some embodiments of the present disclosure.

FIG. 18 illustrates one or more stages of an example of a method for manufacturing an electronic package structure according to some embodiments of the present disclosure.

FIG. 19 illustrates one or more stages of an example of a method for manufacturing an electronic package structure according to some embodiments of the present disclosure.

FIG. 20 illustrates one or more stages of an example of a method for manufacturing an electronic package structure according to some embodiments of the present disclosure.

FIG. 21 illustrates one or more stages of an example of a method for manufacturing an electronic package structure according to some embodiments of the present disclosure.

FIG. 22 illustrates one or more stages of an example of a method for manufacturing an electronic package structure according to some embodiments of the present disclosure.

### DETAILED DESCRIPTION

Common reference numerals are used throughout the drawings and the detailed description to indicate the same or similar components. Embodiments of the present disclosure will be readily understood from the following detailed description taken in conjunction with the accompanying drawings.

The following disclosure provides many different embodiments, or examples, for implementing different features of the provided subject matter. Specific examples of components and arrangements are described below to explain certain aspects of the present disclosure. These are, of course, merely examples and are not intended to be limiting. For example, the formation of a first feature over or on a second feature in the description that follows may include embodiments in which the first and second features are formed or disposed in direct contact, and may also include embodiments in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

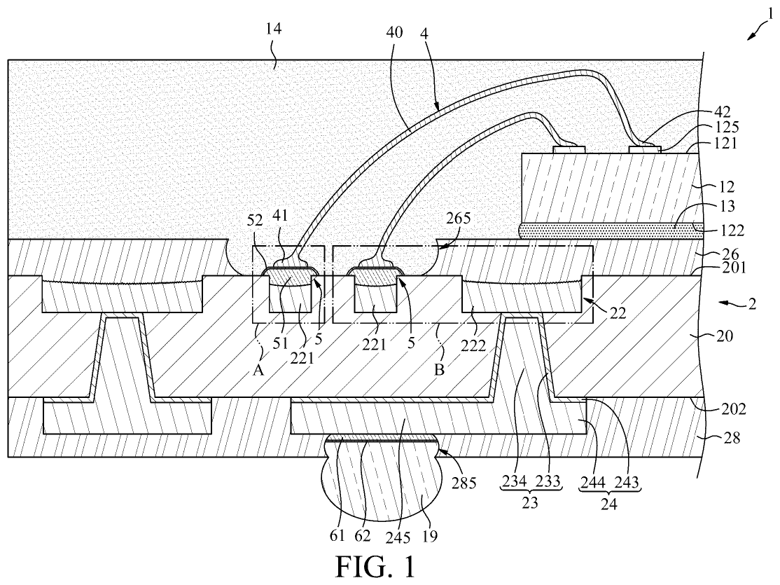

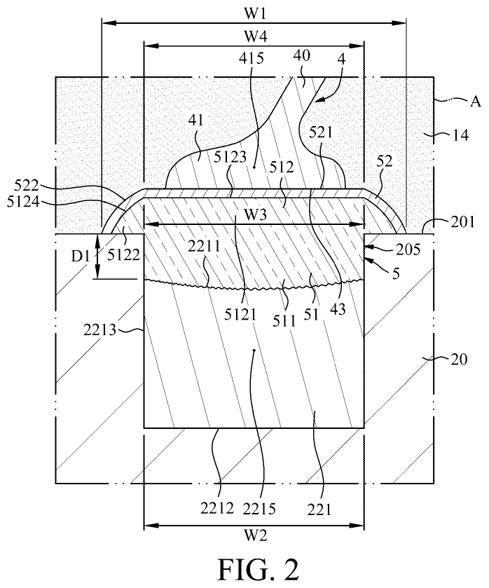

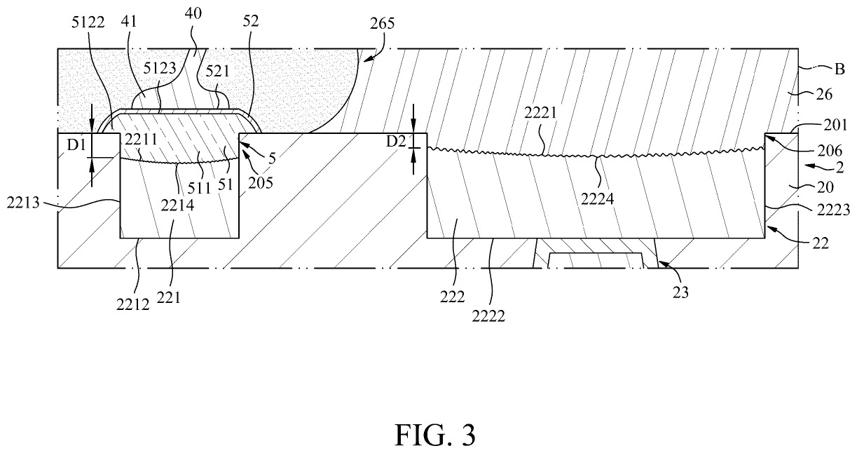

FIG. 1 illustrates a cross-sectional view of a portion of an electronic package structure 1 according to some embodiments of the present disclosure. FIG. 2 illustrates an enlarged view of an area “A” of FIG. 1. FIG. 3 illustrates an enlarged view of an area “B” of FIG. 1. The electronic package structure 1 may include a substrate structure 2, an electronic component 12, at least one conductive wire 4, an encapsulant 14 and at least one external connector 19 (e. g, solder balls).

The substrate structure 2 may be a circuit pattern structure, a redistribution layer (RDL) structure or a wiring structure. The substrate structure 2 may be an embedded trace substrate (ETS). The substrate structure 2 may include a dielectric structure 20, a first circuit layer 22, a booster layer 5, a second circuit layer 24, at least one inner via 23, a first protection layer 26 and a second protection layer 28.

The dielectric structure 20 (e.g., a dielectric layer) may be, or may include, for example, a monocrystalline silicon, a polycrystalline silicon, an amorphous silicon, other suitable materials, or a combination thereof. The dielectric structure 20 may be, or may include, for example, a sheet made from pre-impregnated composite fibers. For example, the dielectric structure 20 may include a cured fiber reinforced resin. A thickness of the dielectric structure 20 may be, for example, about 40 μm to 80 μm. The dielectric structure 20 may include a first surface 201 (e.g., a top surface) and a second surface 202 (e.g., a bottom surface) opposite to the first surface 201. It is noted that the dielectric structure 20 may include, or be formed from, a cured photoimageable dielectric (PID) material such as epoxy or polyimide (PI) or polypropylene (PP) including photoinitiators. In some embodiments, the dielectric structure 20 may be a single layer, a one-piece layer, a one-piece structure or a monolithic structure. In some embodiments, the dielectric structure 20 may include a plurality of dielectric layers.

The first circuit layer 22 may be embedded in the dielectric structure 20, and may be formed by a semi-additive process (SAP) or a modified semi-additive process (MSAP). A material of the first circuit layer 22 may be a conductive metal such as copper, and a thickness of the first circuit layer 22 may be greater than about 10 μm (for example about 15 μm). A portion (e.g., a top surface) of the first circuit layer 22 may be exposed from the first surface 201 of the dielectric structure 20. For example, the dielectric structure 20 does not cover the top surface of the first circuit layer 22. The first circuit layer 22 does not protrude from the first surface 201 of the dielectric structure 20. A line width/line spacing (L/S) of the first circuit layer 22 may be greater than or equal to about 7 μm/about 7 μm, greater than or equal to about 5 μm/about 5 μm, or greater than or equal to about 2 μm/about 2 μm.

In some embodiments, the first circuit layer 22 may include a first portion 221 (e.g., a first pad portion, a first bonding pad or a portion of a first trace) and a second portion 222 (e.g., a second pad portion, a second bonding pad or a portion of a second trace). The first portion 221 of the first circuit layer 22 may have a first surface 2211 (e.g., a top surface), a second surface 2212 (e.g., a bottom surface) opposite to the first surface 2211 and a lateral surface 2213 extending between the first surface 2211 and the second surface 2212. The first portion 221 of the first circuit layer 22 is recessed from the first surface 201 of the dielectric structure 20, and a first distance D1 may be formed between the first surface 2211 of the first portion 221 and the first surface 201 of the dielectric structure 20, so that a recess portion 205 (or a first opening) may be formed above the first surface 2211 of the first portion 221 and below the first surface 201 of the dielectric structure 20. However, in some embodiments, the first surface 2211 of the first portion 221 may be coplanar with or aligned with the first surface 201 of the dielectric structure 20.

Thus, the dielectric structure 20 (e.g., the dielectric layer) may encapsulate the first circuit layer 22. The dielectric structure 20 (e.g., the dielectric layer) may define the recess portion 205 (or the opening) to expose the first surface 2211 (e.g., the top surface) of the first portion 221 (e.g., the first pad portion). An elevation of the first surface 2211 (e.g., the top surface) of the first portion 221 (e.g., the first pad portion) may be lower than an elevation of the first surface 201 (e.g., the top surface) of the dielectric structure 20 (e.g., the dielectric layer).

In addition, a surface roughness value (e.g., in terms of root mean square surface roughness) of the first surface 2211 of the first portion 221 may be greater than about 0.4 μm, and a surface roughness value of the lateral surface 2213 of the first portion 221 may be in a range of about 0.25 μm to about 0.5 μm. For example, the surface roughness of the first surface 2211 (e.g., the top surface) of the first portion 221 of the first circuit layer 22 may be greater than the surface roughness of the lateral surface 2213 of the first portion 221 of the first circuit layer 22. In some embodiments, the first surface 2211 (e.g., the top surface) of the first portion 221 of the first circuit layer 22 may be a concave surface.

A width of the second portion 222 of the first circuit layer 22 may be greater than a width of the first portion 221 of the first circuit layer 22. The second portion 222 of the first circuit layer 22 may have a first surface 2221 (e.g., a top surface), a second surface 2222 (e.g., a bottom surface) opposite to the first surface 2221 and a lateral surface 2223 extending between the first surface 2221 and the second surface 2222. The second portion 222 of the first circuit layer 22 is recessed from the first surface 201 of the dielectric structure 20, and a second distance D2 may be formed between the first surface 2221 of the second portion 222 and the first surface 201 of the dielectric structure 20, so that a recess portion 206 (or a second opening) may be formed above the first surface 2221 of the second portion 222 and below the first surface 201 of the dielectric structure 20. The second distance D2 may be equal to or less than the first distance D1. However, in some embodiments, the first surface 2221 of the second portion 222 may be coplanar with or aligned with the first surface 201 of the dielectric structure 20.

In addition, a surface roughness value (e.g., in terms of root mean square surface roughness) of the first surface 2221 of the second portion 222 may be greater than about 0.4 μm, and a surface roughness value of the lateral surface 2223 of the second portion 222 may be in a range of about 0.25 μm to about 0.5 μm. For example, the surface roughness of the first surface 2221 (e.g., the top surface) of the second portion 222 of the first circuit layer 22 may be greater than the surface roughness of the lateral surface 2223 of the second portion 222 of the first circuit layer 22. In some embodiments, the surface roughness of the first surface 2211 (e.g., the top surface) of the first portion 221 of the first circuit layer 22 may be different from (e.g., greater than or less than) the surface roughness of the first surface 2221 (e.g., the top surface) of the second portion 222 of the first circuit layer 22. In some embodiments, the first surface 2221 (e.g., the top surface) of the second portion 222 of the first circuit layer 22 may be a concave surface. In addition, a bottommost point 2214 of the first surface 2211 (e.g., the top surface) of the first portion 221 of the first circuit layer 22 may be lower than a bottommost point 2224 of the first surface 2221 (e.g., the top surface) of the second portion 222 of the first circuit layer 22.

The booster layer 5 may be also referred to as “an added layer”, “a height-adjusted layer”, “an elevated layer”, or “a thickened layer”. The booster layer 5 may be disposed on the first portion 221 of the first circuit layer 22, and may extend beyond the first surface 201 of the dielectric structure 20. The booster layer 5 may include a first metal material 51 and a second metal material 52 on the first metal material 51. The first metal material 51 and the second metal material 52 may be collectively formed a cap structure or an intermediate structure. The first metal material 51 may be disposed on the first surface 2211 (e.g., the top surface) of the first portion 221 of the first circuit layer 22, and may extend beyond the first surface 201 of the dielectric structure 20. Thus, the first metal material 51 may extend from the first surface 2211 (e.g., the top surface) of the first portion 221 of the first circuit layer 22 to over the first surface 201 of the dielectric structure 20. The first surface 201 of the dielectric structure 20 may horizontally overlap the first metal material 51.

The first metal material 51 may include an upper portion 512 and a lower portion 511. The lower portion 511 may be disposed in the recess portion 205, and may be lower than the first surface 201 of the dielectric structure 20. The lower portion 511 may have a substantially consistent thickness and width. The upper portion 512 may be disposed on the lower portion 511, and may be higher than the first surface 201 of the dielectric structure 20. A maximum width W1 of the upper portion 512 of the first metal material 51 may be greater than a maximum width W2 of the lower portion 511 of the first metal material 51. The maximum width W1 may include the thickness of the second metal material 52. The maximum width W2 of the lower portion 511 of the first metal material 51 may be substantially equal to a width W2 of the first portion 221 of the first circuit layer 22. Thus, the maximum width W1 of the booster layer 5 may be greater than the width W2 of the first portion 221 (e.g., the first pad portion) of the first circuit layer 22. The upper portion 512 of the first metal material 51 may taper away from the first surface 201 of the dielectric structure 20.

The upper portion 512 of the first metal material 51 may include a central portion 5121 and a periphery portion 5122 surrounding the central portion 5121. The central portion 5121 may have a substantially consistent thickness and may have a substantially flat top surface 5123. The periphery portion 5122 may have a lateral surface 5124. Thus, the upper portion 512 of the first metal material 51 may have a flat top surface 5123 and a lateral surface 5124 extending between the flat top surface 5123 and the first surface 201 of the dielectric structure 20. The substantially flat top surface 5123 of the central portion 5121 of the upper portion 512 of the first metal material 51 may be substantially parallel with the first surface 201 of the dielectric structure 20. The periphery portion 5122 may taper away from the central portion 5121. The periphery portion 5122 may contact the first surface 201 of the dielectric structure 20. In addition, a width W3 of the substantially flat top surface 5123 of the central portion 5121 of the upper portion 512 of the first metal material 51 may be less than, substantially equal to, or greater than the width W2 of the first portion 221 of the first circuit layer 22. In some embodiments, the width W3 may be not less than the width W2.

The upper portion 512 and the lower portion 511 may be formed integrally as a monolithic structure. The lateral surface 5124 of the upper portion 512 of the first metal material 51 may be curved or convex. Thus, the first metal material 51 may be substantially in a mushroom shape, or a “T” shape. There may be no interface between the upper portion 512 and the lower portion 511. The first metal material 51 may include nickel (Ni), and may be formed by a deposition process, such as an electroless nickel immersion gold (ENIG) process, or an electroless nickel/electroless palladium/immersion gold (ENEPIG) process. In addition, a surface roughness of the substantially flat top surface 5123 of the central portion 5121 of the upper portion 512 of the first metal material 51 may be less than the surface roughness of the first surface 2211 (e.g., the top surface) of the first portion 221 of the first circuit layer 22.

The second metal material 52 may be disposed between the first metal material 51 and the first end portion 41 of the conductive wire 4. Thus, the second metal material 52 may be configured to enhance a bonding strength between the first end portion 41 of the conductive wire 4 and the booster layer 5. The second metal material 52 may be conformally formed or disposed on the upper portion 512 of the first metal material 51. Thus, the second metal material 52 may cover and contact the top surface 5123 of the upper portion 512 of the first metal material 51 and the lateral surface 5124 of the upper portion 512 of the first metal material 51. The second metal material 52 may be a metal layer that has a substantially consistent thickness. The second metal material 52 may be formed or disposed on the entire top surface of the first metal material 51, and may contact the first surface 201 of the dielectric structure 20. A thickness of the second metal material 52 may be less than a thickness of the central portion 5121 of the upper portion 512 of the first metal material 51 or a thickness of the lower portion 511 of the first metal material 51. In some embodiments, the thickness of the second metal material 52 may be about 0.2 μm to about 10 μm, but it is not limited to this range. The second metal material 52 may include gold (Au), and may be formed by a deposition process, such as an electroless nickel immersion gold (ENIG) process, or an electroless nickel/electroless palladium/immersion gold (ENEPIG) process.

The second metal material 52 may have a substantially flat top surface 521 and a lateral surface 522. The substantially flat top surface 521 may be a substantially flat top surface of the booster layer 5. The substantially flat top surface 521 may be also referred to as “a bonding area”, or “a bonding surface”, or “a receiving surface”. The lateral surface 522 may be a lateral surface of the booster layer 5. The substantially flat top surface 521 of the second metal material 52 may be substantially parallel with the first surface 201 of the dielectric structure 20. In addition, a width W4 of the substantially flat top surface 521 of the second metal material 52 may be less than, substantially equal to, or greater than the width W3 of the substantially flat top surface 5123 of the central portion 5121 of the upper portion 512 of the first metal material 51. An area of the substantially flat top surface 521 of the booster layer 5 may be substantially equal to an area of the top surface 2211 of the first portion 221 of the first circuit layer 22.

In some embodiments, a hardness of the second metal material 52 may be less than a hardness of the first metal material 51. A rigidity of the booster layer 5 may be greater than a rigidity of the first portion 221 of the first circuit layer 22. The booster layer 5 is not conformal with the first portion 221 of the first circuit layer 22.

The second circuit layer 24 may be disposed on the second surface 202 of the dielectric structure 20, and may protrude from the second surface 202 of the dielectric structure 20. A material of the second circuit layer 24 may be a conductive metal such as copper, and the thickness of the second circuit layer 24 may be, for example, about 15 μm. The second circuit layer 24 may be electrically connected to the first circuit layer 22 through an inner via 23. A portion 245 of the second circuit layer 24 is for external connection. The second circuit layer 24 may include a seed layer 243 and a conductive metal 244 on the seed layer 243. The seed layer 243 may be interposed between the conductive metal 244 and the second surface 202 of the dielectric structure 20.

The inner via 23 may be embedded in the dielectric structure 20. The inner via 23 may be a monolithic structure. A first end of the inner via 23 may connect the second surface 2222 (e.g., the bottom surface) of the second portion 222 of the first circuit layer 22, and a second end of the inner via 23 may connect the second circuit layer 24. A vertical distance between the first circuit layer 22 and the second circuit layer 24 may be a thickness or a height of one inner via 23. A width of the first end of the inner via 23 may be less than a width of the second end of the inner via 23. Thus, the inner via 23 may taper toward the first circuit layer 22. In some embodiments, the inner via 23 and the second circuit layer 24 may be formed integrally and concurrently. For example, the inner via 23 may include a seed layer 233 and a conductive metal 234 on the seed layer 233. The seed layer 233 of the inner via 23 and the seed layer 243 of the second circuit layer 24 may be the same layer. The conductive metal 234 of the inner via 23 and the conductive metal 244 of the second circuit layer 24 may be the same layer.

The first protection layer 26 may be disposed on the first surface 201 of the dielectric structure 20, and may define at least one opening 265 to expose the booster layer 5 for external connection. An upper portion of the opening 265 may taper upward, and a lower portion of the opening 265 may taper downward. That is, a sidewall of the opening 265 may include a curved surface. The upper portion of the opening 265 may taper away from the dielectric structure 20 (e.g., the dielectric layer), and the lower portion of the opening 265 may taper toward the dielectric structure 20 (e.g., the dielectric layer). A material of the first protection layer 26 may be a solder mask. The first protection layer 26 may extend into the recess portion 206 so as to cover and contact the first surface 2221 (e.g., the top surface) of the second portion 222 of the first circuit layer 22. The booster layer 5 may be spaced away from the first protection layer 26. That is, the booster layer 5 may not contact the first protection layer 26. In some embodiments, the first portion 221 (e.g., the first pad portion) of the first circuit layer 22 may be spaced away from the first protection layer 26.

The second protection layer 28 may be disposed on the second surface 202 of dielectric structure 20, and may cover the second circuit layer 24. The second protection layer 28 may define at least one opening 285 to expose the portion 245 of the second circuit layer 24 for external connection. For example, the portion 245 of the second circuit layer 24 may be a ball pad. A material of the second protection layer 28 may be a solder mask. An upper portion of the opening 285 may taper upward, and a lower portion of the opening 285 may taper downward. That is, a sidewall of the opening 285 may include a curved surface. A first layer 61 may be formed or disposed on the portion 245 of the second circuit layer 24, and a second layer 62 may be formed or disposed on the first layer 61. A material of the first layer 61 may be same as the material of the first metal material 51 of the booster layer 5, and may include nickel (Ni). A material of the second layer 62 may be same as the material of the second metal material 52 of the booster layer 5, and may include gold (Au). In addition, a plurality of solder balls 19 may be formed or disposed on the second layer 62. The solder balls 19 may include a re-flowable material such as SnAg alloy.

In some embodiments, the L/S of the first circuit layer 22 may be less than an L/S of the second circuit layer 24. For example, the L/S of the second circuit layer 24 may be greater than about 20 μm/about 20 μm or about 50 μm/about 50 μm. Thus, the first circuit layer 22 may be used to be electrically connected to a semiconductor chip, and may be referred to as “chip side”. The second circuit layer 24 may be used to be mounted to the solder balls 19 so as to connect to a motherboard, and may be referred to as “ball side”.

The second circuit layer 24 may be also referred to as “a low-density redistribution layer.” The first circuit layer 22 may be also referred to as “a high-density redistribution layer.” It is noted that a density of a circuit line (including, for example, a trace or a pad) of the high-density redistribution layer is greater than a density of a circuit line of a low-density redistribution layer. That is, the count of the circuit line (including, for example, a trace or a pad) in a unit area of the high-density redistribution layer is greater than the count of the circuit line in an equal unit area of the low-density redistribution layer, such as about 1.2 times or greater, about 1.5 times or greater, or about 2 times or greater, or about 5 times or greater. Alternatively, or in combination, an L/S of the high-density redistribution layer is less than an L/S of the low-density redistribution layer, such as about 90% or less, about 50% or less, or about 20% or less.

The electronic component 12 may be disposed over the first protection layer 26 of the substrate structure 2 and the first surface 201 of the dielectric structure 20. The electronic component 12 may be a semiconductor device such as a semiconductor die or a semiconductor chip. The electronic component 12 may have a first surface 121 (e.g., a top surface or an active surface), a second surface 122 (e.g., a bottom surface or a backside surface) opposite to the first surface 121, and a lateral surface extending between the first surface 121 and the second surface 112. The second surface 122 of the electronic component 12 may be adhered to the first protection layer 26 of the substrate structure 2 through an adhesion layer 13.

The electronic component 12 may include a plurality of electrical contacts 125. The electrical contacts 125 may be disposed adjacent to the first surface 121 (e.g., the active surface) of the electronic component 12. The electrical contacts 125 may be exposed or may protrude from the first surface 121 (e.g., the active surface) for electrical connection. The electrical contacts 125 may be pads, bumps, studs, pillars or posts. In some embodiments, the electrical contacts 125 of the electronic component 12 may be electrically connected to and physically connected to the second metal material 52 of the booster layer 5 of the substrate structure 2 through the conductive wire 4. In other words, the electronic component 12 may be electrically connected to the substrate structure 2 by wire bonding.

The at least one conductive wire 4 may include a plurality of conductive wires 4. Each of the conductive wires 4 may be a bonding wire. In some embodiments, the conductive wires 4 may physically connect and electrically connect the electronic component 12 and the substrate structure 2, and may be configured to transmit signals. In some embodiments, the conductive wires 4 may connect the electrical contacts 125 the electronic component 12 and the second metal material 52 of the booster layer 5 of the substrate structure 2 through wire bonding process. Thus, the conductive wire 4 may be disposed on the booster layer 5. A material of the conductive wire 4 may include copper (Cu), gold (Au), aluminum (Al), or other suitable metal material.

The conductive wire 4 may include a main portion 40, a first end portion 41 and a second end portion 42. The first end portion 41 may be in a substantially circular plate shape, and may directly contact the second metal material 52 of the booster layer 5 of the substrate structure 2. A width of the first end portion 41 may be greater than a width of the main portion 40. The main portion 40 of the conductive wire 4 may be cylindrical, and may pass through the opening 265 of the first protection layer 26. The main portion 40 of the conductive wire 4 may have a substantially consistent width, and may be bent. The second end portion 42 may be a taper tip, and may directly contact the electrical contacts 125 the electronic component 12. The main portion 40, the first end portion 41 and the second end portion 42 may be formed integrally as a monolithic structure. As shown in FIG. 2, the first end portion 41 may have a center point 415. The first portion 221 of the first circuit layer 22 may have a center point 2215. The center point 415 of the first end portion 41 may be aligned with the center point 2215 of the first portion 221 of the first circuit layer 22 in a vertical direction. In some embodiments, the conductive wire 4 may electrically connect and may be distant from or spaced apart from the first portion 221 (e.g., the first pad portion). An elevation of a bottom surface 43 of the conductive wire 4 is higher than an elevation of the first surface 2211 (e.g., the top surface) of the first portion 221 (e.g., the first pad portion) of the first circuit layer 22.

As shown in FIG. 1, the encapsulant 14 may be formed or disposed on the first protection layer 26 of the substrate structure 2. The encapsulant 14 may encapsulate the electronic component 12, the adhesion layer 13 and the conductive wire 4. In addition, the encapsulant 14 may extend into the opening 265 of the first protection layer 26 to contact the first surface 201 of the dielectric structure 20 and the second metal material 52 of the booster layer 5. The first portion 221 of the first circuit layer 22 may be lower than the bottom surface of the encapsulant 14. A material of the encapsulant 14 may be a molding compound with or without fillers.

In the embodiment illustrated in FIG. 1 to FIG. 3, the conductive wire 4 may be electrically connected to the first portion 221 of the first circuit layer 22 through the booster layer 5 (including the first metal material 51 and the second metal material 52). Since the maximum width W1 of the upper portion 512 of the first metal material 51 may be greater than the width W2 of the first portion 221 of the first circuit layer 22, the flat receiving area for receiving (or supporting) the first end portion 41 of the conductive wire 4 may be enlarged. That is, the booster layer 5 may be configured to reduce a risk of the conductive wire 4 to be bonded on the first surface 201 of the dielectric structure 20 during a wire-bonding process. Thus, the reliability of the bonding between the first end portion 41 of the conductive wire 4 and the second metal material 52 of the booster layer 5 may be improved. In addition, the second metal material 52, exemplified by gold, can enhance the bonding between the conductive wire 4 and the first metal material 51, exemplified by nickel.

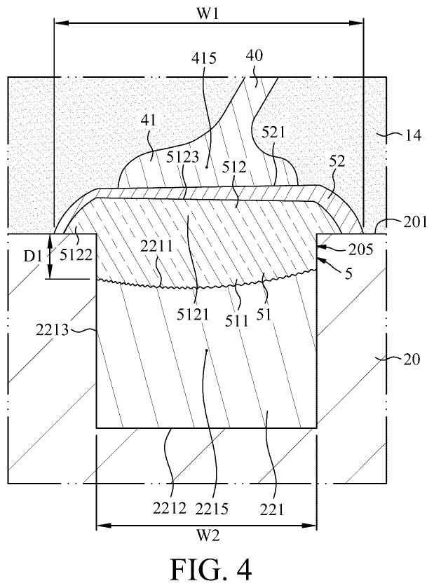

FIG. 4 illustrates a cross-sectional view of a first portion 221 of the first circuit layer 22 and a booster layer 5 according to some embodiments of the present disclosure. The top surface 2211 of the first portion 221 of the first circuit layer 22 may be not symmetrical. The right end of the top surface 2211 of the first portion 221 may be higher than the left end of the top surface 2211 of the first portion 221. In addition, the central portion 5121 of the upper portion 512 of the first metal material 51 may have an inconsistent thickness. The substantially flat top surface 5123 of the central portion 5121 of the upper portion 512 of the first metal material 51 may be not parallel with the first surface 201 of the dielectric structure 20. A size of the right periphery portion 5122 may be different from a size of the left periphery portion 5122. In addition, the second metal material 52 may have an inconsistent thickness.

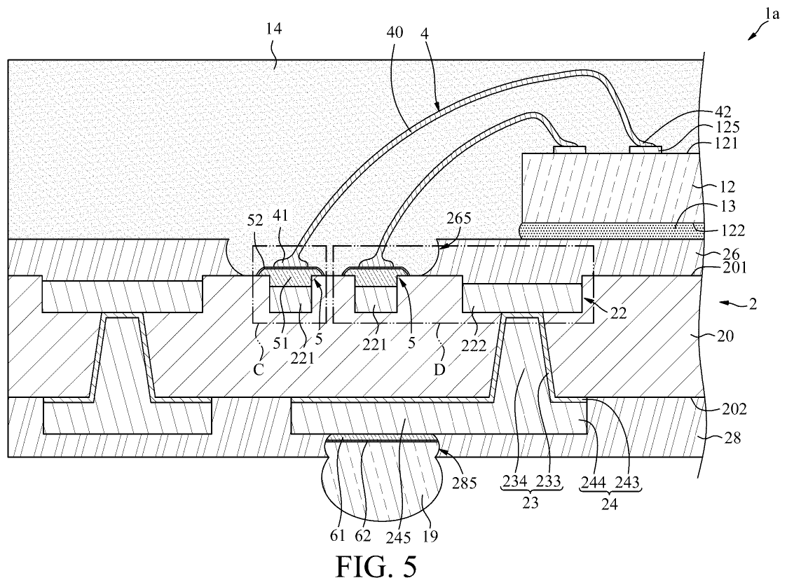

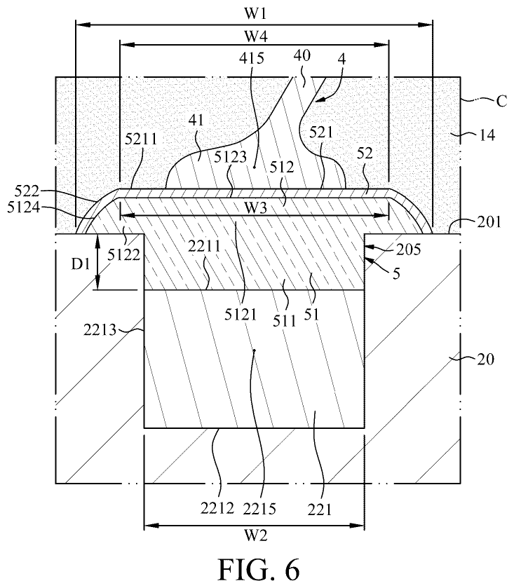

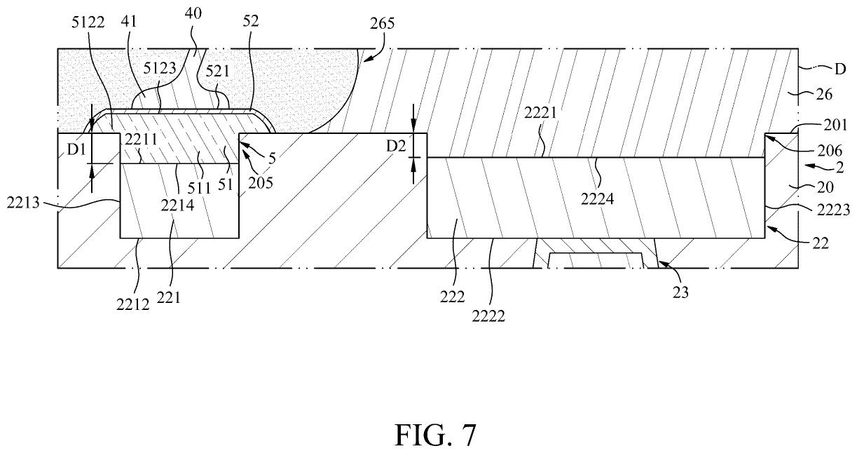

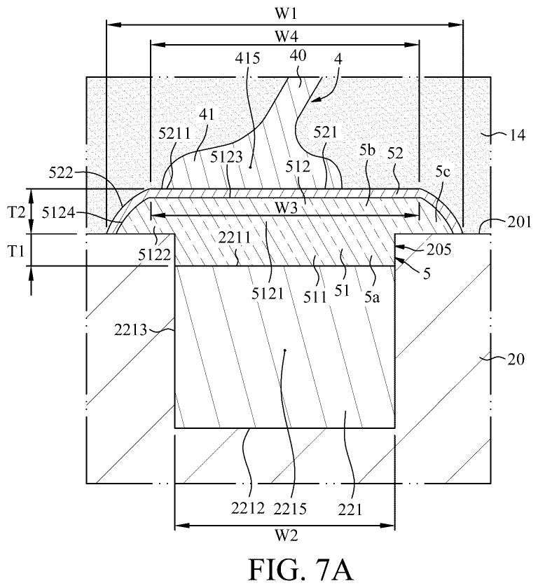

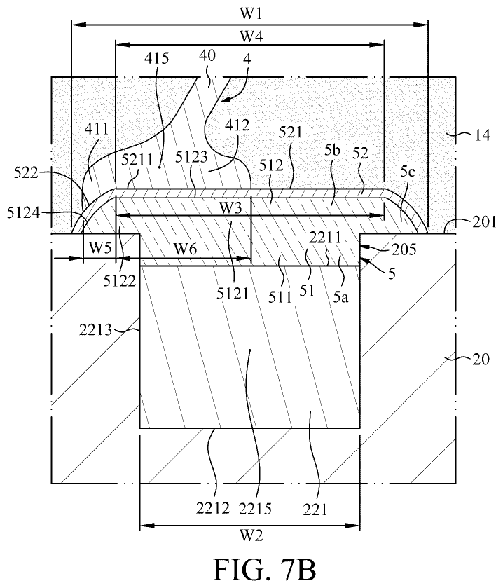

FIG. 5 illustrates a cross-sectional view of a portion of an electronic package structure 1a according to some embodiments of the present disclosure. FIG. 6 illustrates an enlarged view of an area “C” of FIG. 5. FIG. 7 illustrates an enlarged view of an area “D” of FIG. 5. The electronic package structure 1a of FIG. 5 to FIG. 7 is similar to the electronic package structure 1 of FIG. 1 to FIG. 3, and the differences are described as follows. In the electronic package structure 1a, the first surface 2221 (e.g., the top surface) of the second portion 222 of the first circuit layer 22 may be a substantially flat surface. The first surface 2211 (e.g., the top surface) of the first portion 221 of the first circuit layer 22 may be a substantially flat surface. As shown in FIG. 6, the substantially flat top surface 5123 of the central portion 5121 of the upper portion 512 of the first metal material 51 may be substantially parallel with the first surface 2211 (e.g., the top surface) of the first portion 221 of the first circuit layer 22. The width W3 of the substantially flat top surface 5123 of the central portion 5121 of the upper portion 512 of the first metal material 51 may be greater than the width W2 of the first portion 221 of the first circuit layer 22. In addition, the substantially flat top surface 521 of the second metal material 52 (i.e., the substantially flat top surface 521 of the booster layer 5) may be substantially parallel with the first surface 2211 (e.g., the top surface) of the first portion 221 of the first circuit layer 22. The width W4 of the substantially flat top surface 521 of the second metal material 52 (i.e., the substantially flat top surface 521 of the booster layer 5) may be greater than the width W2 of the first portion 221 of the first circuit layer 22. Thus, the booster layer 5 may have the substantially flat top surface 521. The width W4 of the substantially flat top surface 521 of the booster layer 5 may be greater than the width W2 of the first portion 221 (e.g., the first pad portion) of the first circuit layer 22.

As shown in FIG. 6, the flat top surface 521 of the booster layer 5 may include a periphery portion 5211 extending beyond the lateral surface 2213 (e.g., an edge) of the first portion 221 (e.g., the first pad portion) of the first circuit layer 22. The periphery portion 5211 of the flat top surface 521 of the booster layer 5 may be configured to enlarge an area of the flat top surface 521 of the booster layer 5 for receiving (or supporting) the conductive wire 4. The periphery portion 5211 of the flat top surface 521 of the booster layer 5 may be configured to reduce a delamination between the conductive wire 4 and the dielectric layer 20 caused by misalignment between the center 415 of the first end portion 41 of the conductive wire 4 and the center 2215 of the first portion 221 (e.g., the first pad portion) of the first circuit layer 22 during a wire bonding process. It is noted that if the first end portion 41 of the conductive wire 4 is bonded to the first surface 201 (e.g., the top surface) of the dielectric structure 20 (e.g., the dielectric layer), the delamination between the conductive wire 4 and the dielectric layer 20 will occur readily since the bonding strength between the conductive wire 4 and the dielectric layer 20 is relatively low. In some embodiments, the booster layer 5 may be configured to prevent the first end portion 41 of the conductive wire 4 from contacting the first surface 201 (e.g., the top surface) of the dielectric structure 20 (e.g., the dielectric layer) during the wire bonding process. In some embodiments, the booster layer 5 may be configured to provide a flat receiving area (i.e., the substantially flat top surface 521) not less than an area of the top surface 2211 of the first portion 221 (e.g., the first pad portion) for receiving (or supporting) the conductive wire 4 during a wire bonding process.

FIG. 7A illustrates an enlarged cross-sectional view of a portion of an electronic package structure according to some embodiments of the present disclosure. The structure illustrated in FIG. 7A is similar to the structure illustrated in FIG. 6, except for the position of the first end portion 41 of the conductive wire 4. As shown in FIG. 7A, even the center 415 of the first end portion 41 of the conductive wire 4 is slightly misaligned with the center 2215 of the first portion 221 (e.g., the first pad portion) of the first circuit layer 22 during a wire bonding process, the entire first end portion 41 of the conductive wire 4 may be still disposed on the substantially flat top surface 521 of the booster layer 5 due to the periphery portion 5211 of the flat top surface 521 of the booster layer 5. Therefore, the reliability of the bonding between the first end portion 41 of the conductive wire 4 and the second metal material 52 of the booster layer 5 may be secured.

In addition, the booster layer 5 may include a lower portion 5a and an upper portion 5b on the lower portion 5a. The lower portion 5a of the booster layer 5 may be the lower portion 511 of the first metal material 51, which is lower than the first surface 201 (e.g., the top surface) of the dielectric structure 20 (e.g., the dielectric layer). The upper portion 5b of the booster layer 5 may include the upper portion 512 of the first metal material 51 and the second metal material 52. A width W1 of the upper portion 5b of the booster layer 5 may be greater than the width W2 of the first portion 221 (e.g., the first pad portion) of the first circuit layer 22. A thickness T1 of the lower portion 5a of the booster layer 5 may be less than a thickness T2 of the upper portion 5b of the booster layer 5. As shown in FIG. 7A, the upper portion 5b of the booster layer 5 may include a periphery portion 5c. The periphery portion 5c of the booster layer 5 may include the periphery portion 5122 of the upper portion 512 of the first metal material 51 and a portion of the second metal material 52 on the periphery portion 5122. The periphery portion 5c of the booster layer 5 may taper outward. That is, the periphery portion 5c of the booster layer 5 may taper away from a center of the upper portion 5b. Further, the periphery portion 5c of the booster layer 5 may taper upward. That is, the periphery portion 5c of the booster layer 5 may taper away from the first surface 201 of the dielectric structure 20.

FIG. 7B illustrates an enlarged cross-sectional view of a portion of an electronic package structure according to some embodiments of the present disclosure. The structure illustrated in FIG. 7B is similar to the structure illustrated in FIG. 7A, except for the position of the first end portion 41 of the conductive wire 4. As shown in FIG. 7A, the center 415 of the first end portion 41 of the conductive wire 4 is severely misaligned with the center 2215 of the first portion 221 (e.g., the first pad portion) of the first circuit layer 22 during a wire bonding process.

The first end portion 41 of the conductive wire 4 may include a first portion 411 and a second portion 412. The first portion 411 may extend beyond the flat top surface 521 of the booster layer 5 and may contact the lateral surface 522 of the booster layer 5. The first portion 411 of the conductive wire 4 may partially cover the lateral surface 522 of the booster layer 5. That is, the first portion 411 of the conductive wire 4 may cover and contact a portion of the lateral surface 522 of the booster layer 5, and another portion of the lateral surface 522 of the booster layer 5 may be exposed by the first portion 411 of the conductive wire 4. The first portion 411 of the conductive wire 4 may not cover and contact the first surface 201 (e.g., the top surface) of the dielectric structure 20 (e.g., the dielectric layer). The second portion 412 may be disposed on the flat top surface 521 of the booster layer 5. A horizontal width W5 of the first portion 411 of the first end portion 41 of the conductive wire 4 may be greater than a horizontal width W6 of the second portion 412 of the first end portion 41 of the conductive wire 4. Therefore, the reliability of the bonding between the first end portion 41 of the conductive wire 4 and the second metal material 52 of the booster layer 5 may be still secured.

In a comparative embodiment, a bonding pad may protrude from a top surface of the dielectric structure. The bonding pad may be in a trapezoid shape after an etching process. An area of a top surface (i.e., a bonding surface) of the bonding pad is less than an area of a bottom surface of the bonding pad. A slanted lateral surface extends between the top surface and the bottom surface. During a bonding process, since the top surface (i.e., the bonding surface) is relatively small, an end portion of a conductive wire will readily contact the slanted lateral surface when the end portion of a conductive wire moves downward. As the moving direction of the conductive wire is not orthogonal with the slanted lateral surface, the end portion of the conductive wire will slide on the slanted lateral surface and then is guided to contact the top surface of the dielectric structure. As a result, the delamination between the conductive wire and the dielectric structure will occur readily since the bonding strength between the conductive wire and the dielectric structure is relatively low.

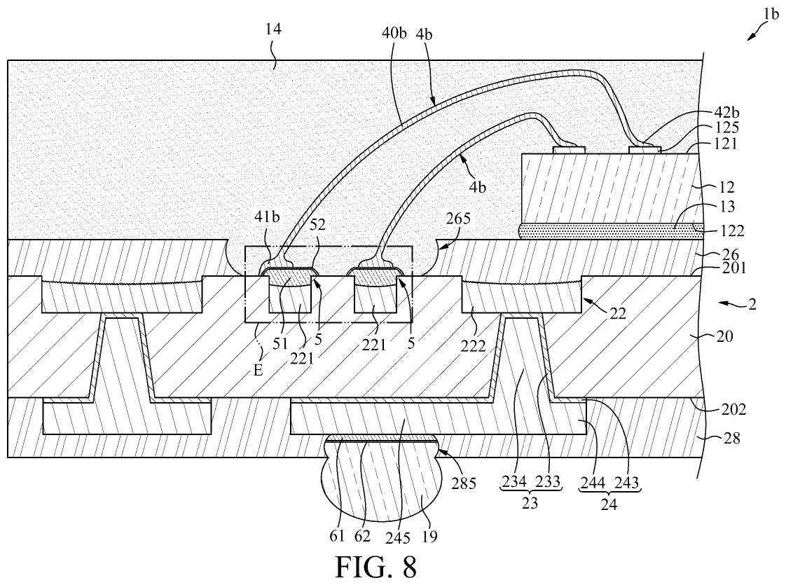

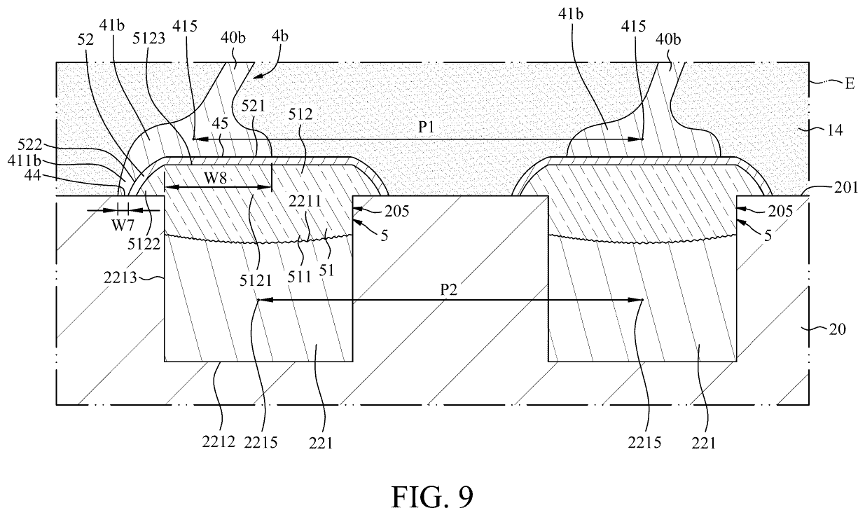

FIG. 8 illustrates a cross-sectional view of a portion of an electronic package structure 1b according to some embodiments of the present disclosure. FIG. 9 illustrates an enlarged view of an area “E” of FIG. 8. The electronic package structure 1b of FIG. 8 and FIG. 9 is similar to the electronic package structure 1 of FIG. 1 to FIG. 3, and the differences are described as follows. In the electronic package structure 1b, the conductive wire 4b may include a main portion 40b, a first end portion 41b and a second end portion 42b. The main portion 40b and the second end portion 42b of the conductive wire 4b of FIG. 8 and FIG. 9 may be same as the main portion 40 and the second end portion 42 of the conductive wire 4 of FIG. 1 to FIG. 3. The center point 415 of the first end portion 41b may be misaligned with or shifted with the center point 2215 of the first portion 221 of the first circuit layer 22 in the vertical direction. Due to the material and the structure of the booster layer 5 (including the first metal material 51 and the second metal material 52), the bonding between the second metal material 52 of the booster layer 5 and the first end portion 41b may be still secured.

In some embodiments, a portion 411b of the first end portion 41b of the conductive wire 4b may contact the first surface 201 of the dielectric structure 20 of the substrate structure 2. Thus, the portion 411b of the conductive wire 4b may overlap the upper portion 512 of the first metal material 51 of the booster layer 5 in a direction parallel with the first surface 201 (e.g., the top surface) of the dielectric structure 20 (e.g., the dielectric layer). In addition, a pitch P1 between the conductive wires 4b may be different from (e.g., less than or greater than) a pitch P2 between the first portions 221 of the first circuit layer 22. The pitch P1 may be defined as a distance between two center points 415 of two adjacent first end portions 41b of the conductive wires 4b. The pitch P2 may be defined as a distance between two center points 2215 of two first portions 221 of the first circuit layer 22. Thus, the pitch P1 of the conductive wires may be different from (e.g., less than or greater than) the pitch P2 of the first portions 221 of the first circuit layer 22.

As shown in FIG. 9, in the cross section, a width W7 of a contact surface 44 between the first end portion 41b of the conductive wire 4b and the first surface 201 (e.g., the top surface) of the dielectric structure 20 (e.g., the dielectric layer) may be less than a width W8 of a contact surface 45 between the first end portion 41b of the conductive wire 4b and the flat top surface 521 of the booster layer 5.

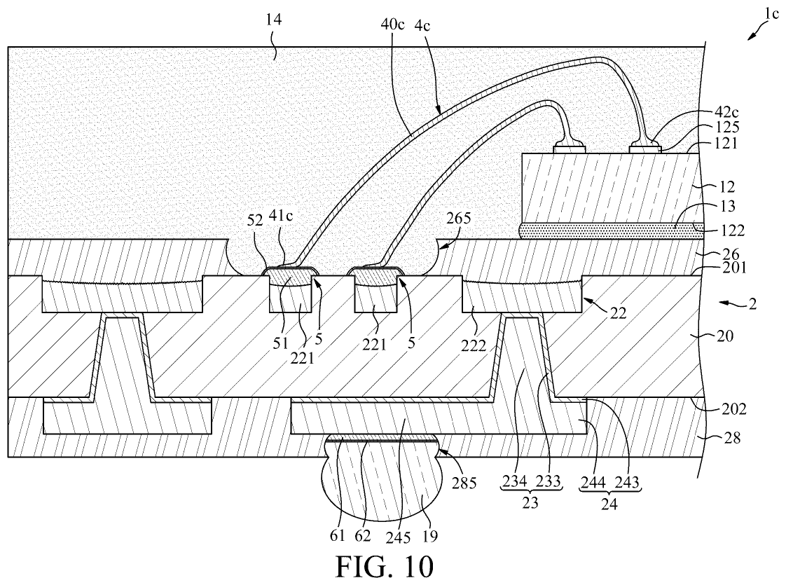

FIG. 10 illustrates a cross-sectional view of a portion of an electronic package structure 1c according to some embodiments of the present disclosure. The electronic package structure 1c of FIG. 10 is similar to the electronic package structure 1 of FIG. 1 to FIG. 3, and the differences are described as follows. In the electronic package structure 1c, the conductive wire 4c may include a main portion 40c, a first end portion 41c and a second end portion 42c. The first end portion 41c may be a taper tip, and may directly contact the second metal material 52 of the booster layer 5. The main portion 40c of the conductive wire 4c may be cylindrical, and may pass through the opening 265 of the first protection layer 26. The main portion 40c of the conductive wire 4c may have a substantially consistent width, and may be bent. The second end portion 42c may be in a substantially circular plate shape, and may directly contact the electrical contact 125 the electronic component 12. A width of the second end portion 42c may be greater than a width of the main portion 40c.

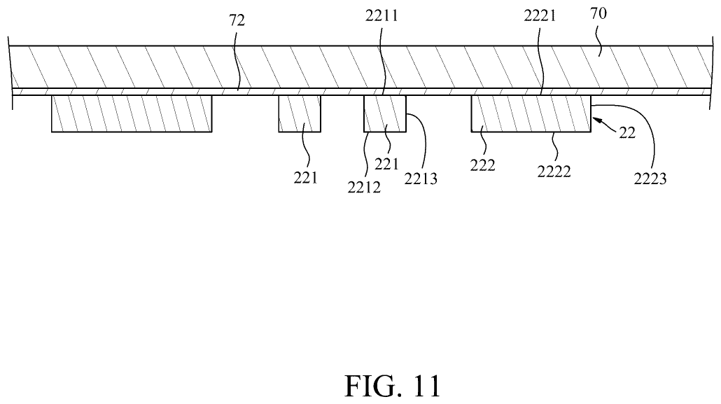

FIG. 11 through FIG. 22 illustrate a method for manufacturing an electronic package structure according to some embodiments of the present disclosure. In some embodiments, the method is for manufacturing the electronic package structure 1 shown in FIG. 1 to FIG. 3.

Referring to FIG. 11, a carrier 70 and a metal foil 72 may be provided. The metal foil 72 may be disposed on a surface of the carrier 70. Although a manufacturing process performed on one side of the carrier 70 is shown, it is understood that the manufacturing process may be performed on the other side of the carrier 70 in a similar manner. For example, the manufacturing process may be performed on both sides of the carrier 70.

Then, a first circuit layer 22 may be formed or disposed on the metal foil 72, for example by a plating technique. A material of the first circuit layer 22 may be a conductive metal such as copper. In some embodiments, the first circuit layer 22 may include a first portion 221 (e.g., a bonding pad or a portion of a trace) and a second portion 222 (e.g., a bonding pad or a portion of a trace). The first portion 221 of the first circuit layer 22 may have a first surface 2211 (e.g., a top surface), a second surface 2212 (e.g., a bottom surface) opposite to the first surface 2211 and a lateral surface 2213 extending between the first surface 2211 and the second surface 2212.

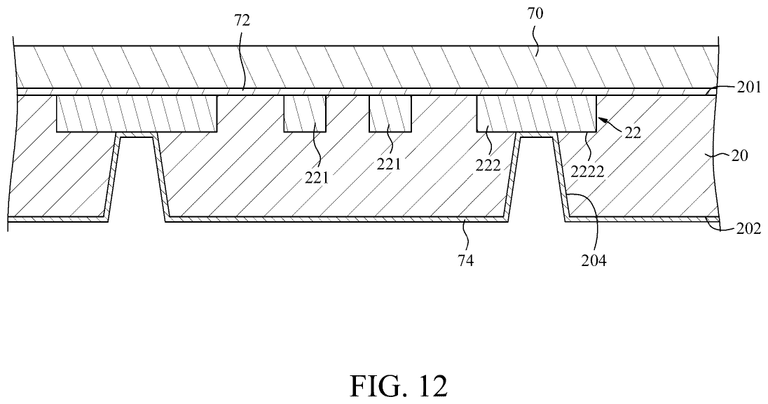

The second portion 222 of the first circuit layer 22 may have a first surface 2221 (e.g., a top surface), a second surface 2222 (e.g., a bottom surface) opposite to the first surface 2221 and a lateral surface 2223 extending between the first surface 2221 and the second surface 2222. The lateral surface 2213 of the first portion 221 and the lateral surface 2223 of the second portion 222 may be treated with a brown oxide treatment to facilitate a lamination process of the dielectric structure 20 (e.g., in FIG. 12), thus, a surface roughness value of the lateral surface 2213 of the first portion 221 may be in a range of about 0.25 μm to about 0.5 μm, and a surface roughness value of the lateral surface 2223 of the second portion 222 may be in a range of about 0.25 μm to about 0.5 μm.

Referring to FIG. 12, a dielectric structure 20 may be formed or disposed (e.g., stacked or laminated) on the metal foil 72 to cover the first circuit layer 22. The dielectric structure 20 may have a first surface 201 and a second surface 202 opposite to the first surface 201. Then, a plurality of openings 204 may be formed on the second surface 202 of the dielectric structure 20 to expose a portion of the second surface 2222 of the second portion 222 of the first circuit layer 22. Then, a seed layer 74 may be formed or disposed on the second surface 202 and the openings 204 of the dielectric structure 20.

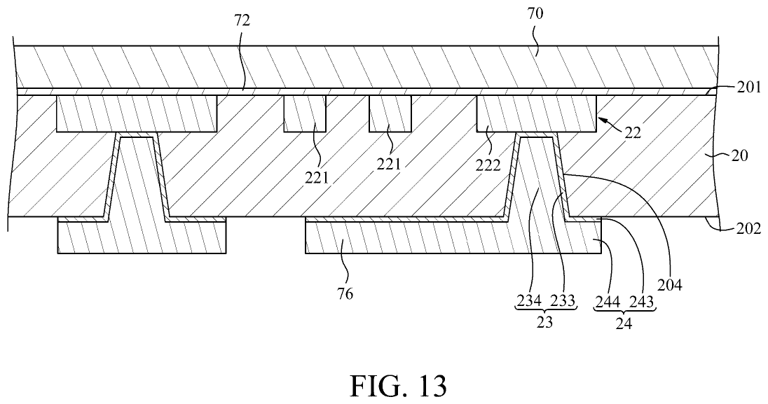

Referring to FIG. 13, a conductive material 76 may be formed or disposed on the seed layer 74. Thus, the conductive material 76 may be formed or disposed on the second surface 202 and the openings 204 of the dielectric structure 20. Then, the conductive material 76 and the seed layer 74 may be patterned to form a second circuit layer 24 and at least one inner via 23.

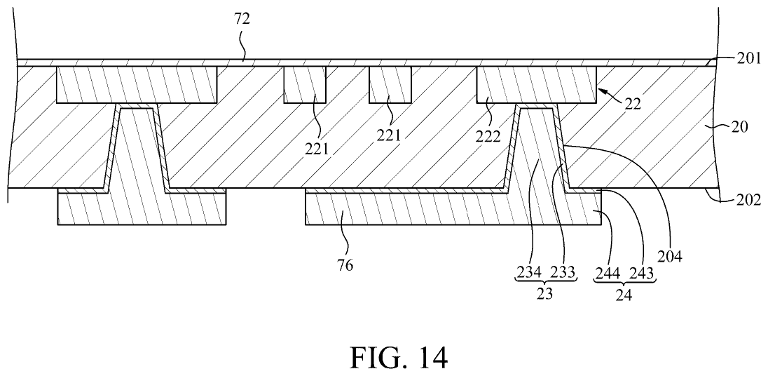

Referring to FIG. 14, the carrier 70 may be removed from the metal foil 72.

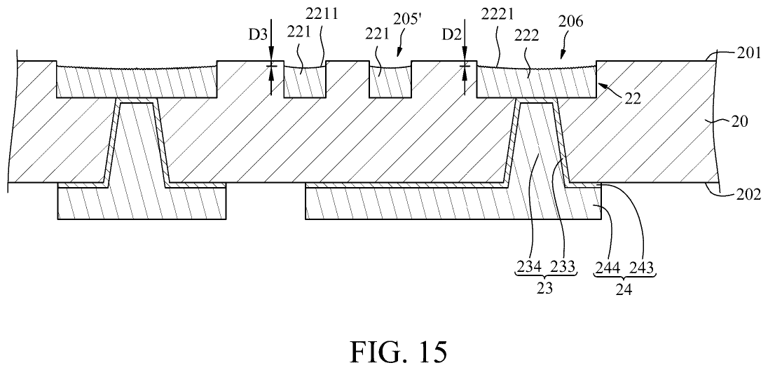

Referring to FIG. 15, the metal foil 72 may be removed by, for example, etching. Thus, a portion (e.g., the top surface) of the first circuit layer 22 may be exposed from the first surface 201 of the dielectric structure 20. In some embodiments, the top surface of the first circuit layer 22 may be over etched, thus, the first circuit layer 22 may be recessed from the first surface 201 of the dielectric structure 20. For example, the second portion 222 of the first circuit layer 22 may be recessed from the first surface 201 of the dielectric structure 20, and a second distance D2 may be formed between the first surface 2221 of the second portion 222 and the first surface 201 of the dielectric structure 20, so that a recess portion 206 may be formed above the first surface 2221 of the second portion 222 and below the first surface 201 of the dielectric structure 20. In addition, the first portion 221 of the first circuit layer 22 may be recessed from the first surface 201 of the dielectric structure 20, and a third distance D3 may be formed between the first surface 2211 of the first portion 221 and the first surface 201 of the dielectric structure 20, so that a recess portion 205′ may be formed above the first surface 2211 of the first portion 221 and below the first surface 201 of the dielectric structure 20. The third distance D3 may be substantially equal to the second distance D2.

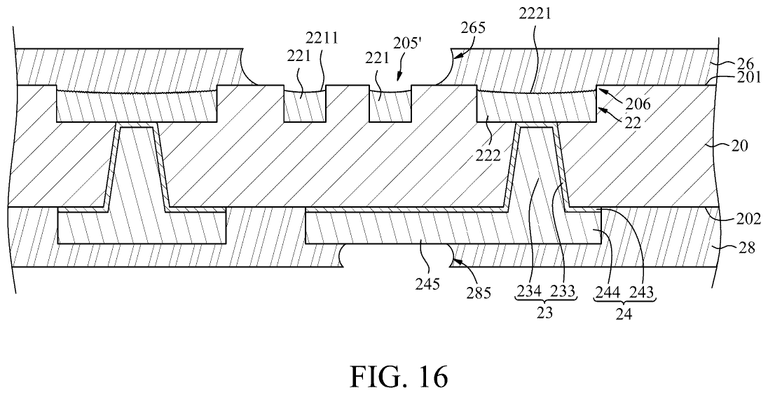

Referring to FIG. 16, a first protection layer 26 may be formed or disposed on the first surface 201 of the dielectric structure 20, and may define at least one opening 265 to expose the recess portion 205′. The first protection layer 26 may extend into the recess portion 206 so as to cover and contact the first surface 2221 (e.g., the top surface) of the second portion 222 of the first circuit layer 22. A second protection layer 28 may be formed or disposed on the second surface 202 of the dielectric structure 20, and may cover the second circuit layer 24. The second protection layer 28 may define at least one opening 285 to expose a portion 245 of the second circuit layer 24.

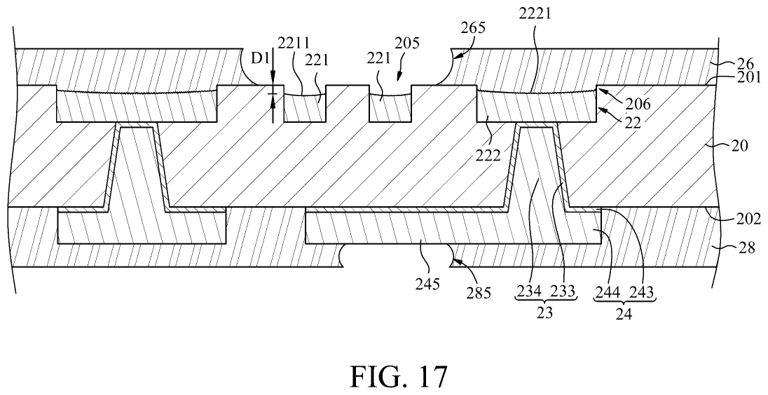

Referring to FIG. 17, a pretreatment process may be conducted, so that the first portion 221 of the first circuit layer 22 may be further etched. A first distance D1 may be formed between the first surface 2211 of the first portion 221 and the first surface 201 of the dielectric structure 20, so that a recess portion 205 may be formed above the first surface 2211 of the first portion 221 and below the first surface 201 of the dielectric structure 20. The first distance D1 may be greater than the third distance D3. Thus, the recess portion 205 may be deeper than the recess portion 205′.

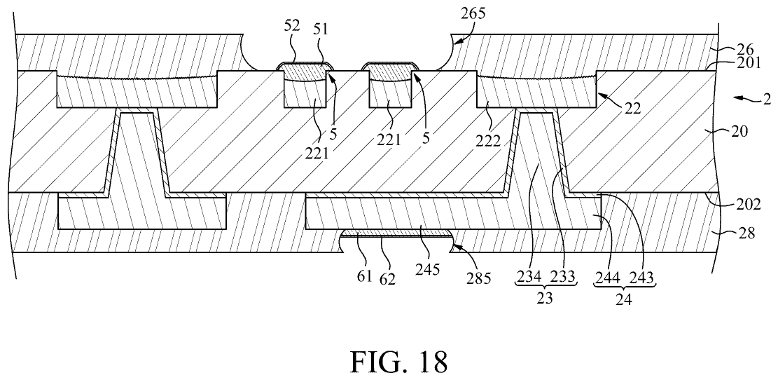

Referring to FIG. 18, a booster layer 5 may be formed or disposed in the recess portion 205 and on the first portion 221 of the first circuit layer 22. The booster layer 5 may include a first metal material 51 and a second metal material 52. The first metal material 51 may be formed or disposed in the recess portion 205, and may extend beyond the first surface 201 of the dielectric structure 20. The first metal material 51 may include nickel (Ni), and may be formed by a deposition process, such as an electroless nickel immersion gold (ENIG) process, or an electroless nickel/electroless palladium/immersion gold (ENEPIG) process. Then, the second metal material 52 may be conformally formed or disposed on the first metal material 51. The second metal material 52 may be a metal layer that has a substantially consistent thickness. The second metal material 52 may be formed or disposed on the entire top surface of the first metal material 51, and may contact the first surface 201 of the dielectric structure 20. The second metal material 52 may include gold (Au), and may be formed by a deposition process, such as an electroless nickel immersion gold (ENIG) process, or an electroless nickel/electroless palladium/immersion gold (ENEPIG) process.

In addition, a first layer 61 may be formed or disposed on the portion 245 of the second circuit layer 24, and a second layer 62 may be formed or disposed on the first layer 61. A material of the first layer 61 may be same as the material of the first metal material 51 of the booster layer 5, and may include nickel (Ni). A material of the second layer 62 may be same as the material of the second metal material 52 of the booster layer 5, and may include gold (Au). Meanwhile, a substrate structure 2 may be formed.

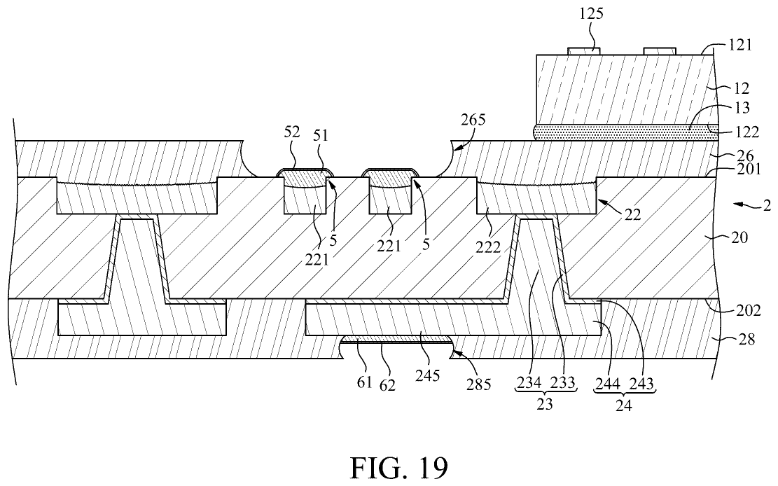

Referring to FIG. 19, an electronic component 12 may be disposed over the first protection layer 26 of the substrate structure 2. The electronic component 12 may have a first surface 121 (e.g., a top surface or an active surface), a second surface 122 (e.g., a bottom surface or a backside surface) opposite to the first surface 121, and a lateral surface extending between the first surface 121 and the second surface 112. The second surface 122 of the electronic component 12 may be adhered to the first protection layer 26 of the substrate structure 2 through an adhesion layer 13. The electronic component 12 may include a plurality of electrical contacts 125. The electrical contacts 125 may be disposed adjacent to the first surface 121 (e.g., the active surface) of the electronic component 12.

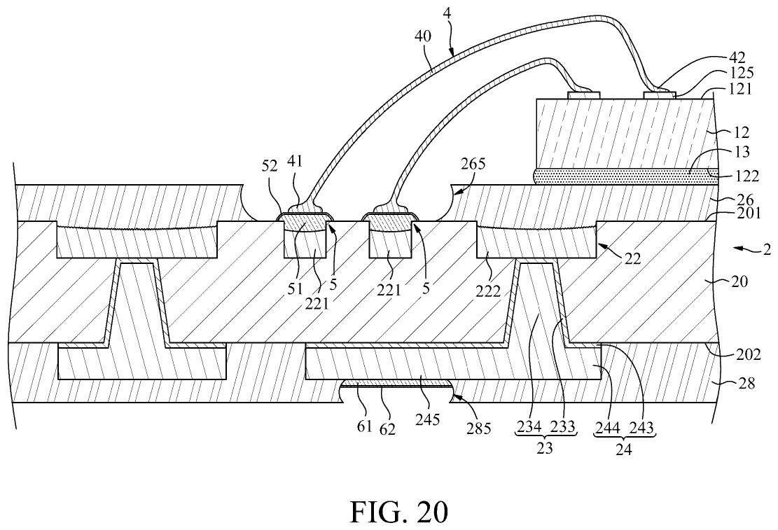

Referring to FIG. 20, a plurality of conductive wires 4 may be formed or disposed to electrically connect the electrical contacts 125 of the electronic component 12 and the second metal material 52 of the booster layer 5 of the substrate structure 2. In other words, the electronic component 12 may be electrically connected to the substrate structure 2 by wire bonding. Each of the conductive wires 4 may be a bonding wire. A material of the conductive wire 4 may include copper (Cu), gold (Au), aluminum (Al), or other suitable metal material. The conductive wire 4 may include a main portion 40, a first end portion 41 and a second end portion 42. The first end portion 41 may be in a substantially circular plate shape, and may directly contact the second metal material 52 of the booster layer 5 of the substrate structure 2. A width of the first end portion 41 may be greater than a width of the main portion 40. The main portion 40 of the conductive wire 4 may be cylindrical, and may pass through the opening 265 of the first protection layer 26. The main portion 40 of the conductive wire 4 may have a substantially consistent width, and may be bent. The second end portion 42 may be a taper tip, and may directly contact the electrical contacts 125 the electronic component 12.

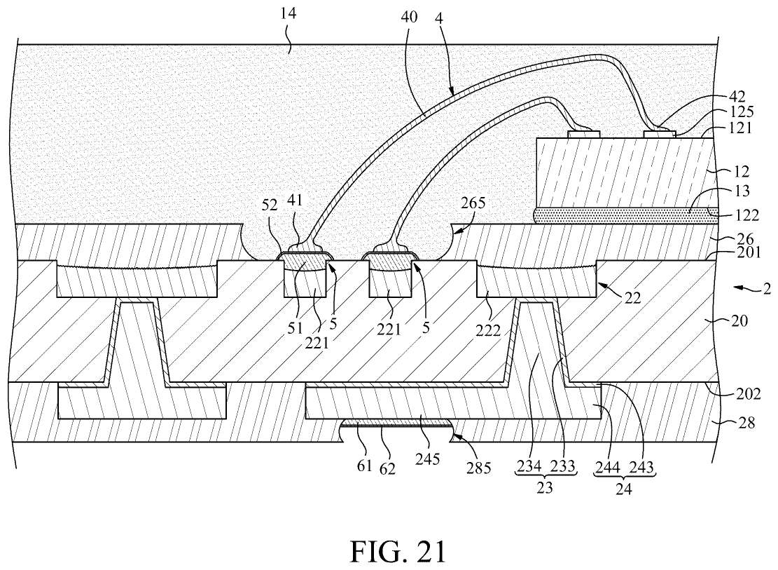

Referring to FIG. 21, an encapsulant 14 may be formed or disposed on the first protection layer 26 of the substrate structure 2. The encapsulant 14 may encapsulate the electronic component 12, the adhesion layer 13 and the conductive wires 4. In addition, the encapsulant 14 may extend into the opening 265 of the first protection layer 26 to contact the first surface 201 of the dielectric structure 20 and the second metal material 52 of the booster layer 5. A material of the encapsulant 14 may be a molding compound with or without fillers.

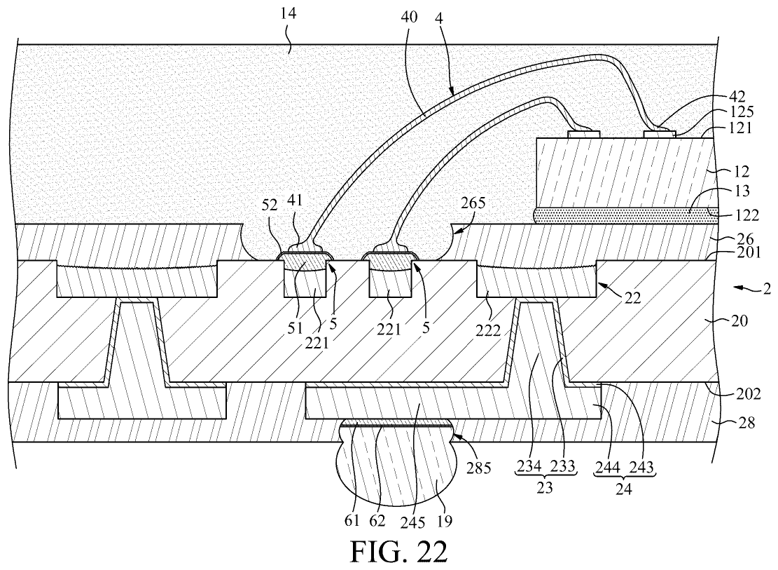

Referring to FIG. 22, a plurality of solder balls 19 may be formed or disposed on the second layer 62. The solder balls 19 may include a re-flowable material such as SnAg alloy.

Then, a singulation process may be conducted to obtain a plurality of electronic package structures 1 of FIG. 1 to FIG. 3.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of embodiments of this disclosure are not deviated from by such an arrangement.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, a first numerical value can be deemed to be “substantially” the same or equal to a second numerical value if the first numerical value is within a range of variation of less than or equal to ±10% of the second numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%.

Two surfaces can be deemed to be coplanar or substantially coplanar if a displacement between the two surfaces is no greater than 5 μm, no greater than 2 μm, no greater than 1 μm, or no greater than 0.5 μm. A surface can be deemed to be substantially flat if a displacement between a highest point and a lowest point of the surface is no greater than 5 μm, no greater than 2 μm, no greater than 1 μm, or no greater than 0.5 μm.

As used herein, the singular terms “a,” “an,” and “the” may include plural referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific embodiments thereof, these descriptions and illustrations are not limiting. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other embodiments of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic package structure, comprising:
a substrate structure, comprising:
a circuit layer including a pad portion;
a dielectric layer encapsulating the circuit layer, and defining an opening exposing a top surface of the pad portion, wherein an elevation of the top surface of the pad portion is lower than an elevation of a top surface of the dielectric layer; and
a booster layer disposed on the pad portion of the circuit layer and extending beyond the top surface of the dielectric layer; and
a conductive wire disposed on the booster layer.

2. The electronic package structure of claim 1, wherein in a cross section, a width of an upper portion of the booster layer is greater than a width of the pad portion of the circuit layer.

3. The electronic package structure of claim 2, wherein the booster layer has a flat top surface, wherein in a cross section, a width of the flat top surface of the booster layer is greater than the width of the pad portion of the circuit layer.

4. The electronic package structure of claim 3, wherein the flat top surface of the booster layer includes a periphery portion extending beyond a lateral surface of the pad portion of the circuit layer, and configured to enlarge an area of the flat top surface of the booster layer for supporting the conductive wire.

5. The electronic package structure of claim 3, wherein the conductive wire includes a first portion extending beyond the flat top surface of the booster layer and a second portion disposed on the flat top surface of the booster layer, wherein a horizontal width of the first portion of the conductive wire is greater than a horizontal width of the second portion of the conductive wire.

6. The electronic package structure of claim 5, wherein the first portion of the conductive wire partially covers a lateral surface of the booster layer.

7. The electronic package structure of claim 5, wherein the first portion of the conductive wire does not contact the top surface of the dielectric layer.

8. The electronic package structure of claim 1, wherein the booster layer includes a first metal material and a second metal material between the first metal material and the conductive wire, wherein the second metal material is configured to enhance a bonding strength between the conductive wire and the booster layer.

9. The electronic package structure of claim 8, wherein the second metal material covers a top surface of the first metal material and a lateral surface of the first metal material.

10. The electronic package structure of claim 1, wherein the booster layer includes a lower portion lower than the top surface of the dielectric layer and an upper portion on the lower portion, wherein a thickness of the lower portion of the booster layer is less than a thickness of the upper portion of the booster layer.

11. The electronic package structure of claim 1, wherein the upper portion of the booster layer includes a periphery portion tapering outward or upward.

12. The electronic package structure of claim 1, wherein a rigidity of the booster layer is greater than a rigidity of the pad portion of the circuit layer.

13. An electronic package structure, comprising:
a circuit layer including a pad portion;
a dielectric layer encapsulating the circuit layer, and defining an opening exposing a top surface of the pad portion, wherein the top surface of the pad portion is lower than a top surface of the dielectric layer; and
a booster layer disposed on the pad portion of the circuit layer and configured to reduce a delamination between a conductive wire and the dielectric layer caused by a misalignment between the conductive wire and the pad portion of the circuit layer during a wire bonding process.

14. The electronic package structure of claim 13, wherein a portion of the conductive wire overlaps the booster layer in a direction parallel with the top surface of the dielectric layer.

15. The electronic package structure of claim 14, wherein in a cross section, a width of a contact surface between the conductive wire and the dielectric layer is less than a width of a contact surface between the conductive wire and a flat top surface of the booster layer.

16. The electronic package structure of claim 13, wherein a top surface of the pad portion of the circuit layer is concave.

17. The electronic package structure of claim 13, wherein a surface roughness of a top surface of the pad portion of the circuit layer is less than a surface roughness of a top surface of a second pad portion of the circuit layer.

18. The electronic package structure of claim 13, further comprising:
a protection layer disposed on the top surface of the dielectric layer, and defining an opening to expose the booster layer, wherein the booster layer is spaced away from the protection layer, wherein an upper portion of the opening tapers away from the dielectric layer, and a lower portion of the opening tapers toward the dielectric layer.

19. An electronic package structure, comprising:
a substrate structure, comprising:
a circuit layer including a pad portion; and
a dielectric layer encapsulating the circuit layer, and defining an opening exposing a top surface of the pad portion, wherein the top surface of the pad portion is lower than a top surface of the dielectric layer; and
a conductive wire electrically connecting and distant from the pad portion, wherein an elevation of a bottom surface of the conductive wire is higher than an elevation of the top surface of the pad portion.

20. The electronic package structure of claim 19, wherein the circuit layer further includes a second pad portion, the dielectric layer further defines a second opening exposing the second pad portion, wherein the substrate structure further comprises:
a protection layer disposed on the top surface of the dielectric layer, and covering the second pad portion, wherein the pad portion is spaced away from the protection layer.
